(19) United States
(12) Patent Application Publication
(10) Pub. No.: US 2025/0212645 A1
(43) Pub. Date: Jun. 26, 2025

(54) Display Apparatus

(71) Applicant: LG Display Co., Ltd., Seoul (KR)

(72) Inventors: Hoonsok Son, Seoul (KR); Goeun Lim, Mokpo-si (KR); Hansun Park, Paju-si (KR)

(21) Appl. No.: 18/949,535

(22) Filed: Nov. 15, 2024

(30) Foreign Application Priority Data
Dec. 26, 2023 (KR) 10-2023-0191516

(51) Int. Cl. H10K 59/38; H10K 59/12; H10K 59/121; H10K 59/122; H10K 59/131; H10K 59/80; H10K 102/00

(52) U.S. Cl. CPC H10K 59/38; H10K 59/1201; H10K 59/1213; H10K 59/122; H10K 59/131; H10K 59/878; H10K 2102/351

(57) ABSTRACT

A display apparatus includes a substrate having a plurality of sub-pixel areas; a plurality of transistors disposed on the substrate; a planarization layer on the plurality of transistors; a plurality of partitioning patterns on the planarization layer and arranged to be spaced apart from each other; a low-reflective metal pattern on each of the partitioning patterns; an anode electrode disposed on each of the low-reflective metal pattern and the planarization layer; an organic light-emitting layer on the anode electrode; a cathode electrode disposed on the organic light-emitting layer; and a plurality of color filters disposed on the cathode electrode and arranged in a corresponding manner to the plurality of sub-pixel areas, respectively, wherein a vertical level of an upper surface of at least one color filter of the plurality of color filters is higher than a vertical level of an upper surface of each of the other color filters thereof.

### CROSS-REFERENCE TO RELATED APPLICATION

This application claims priority to Republic of Korea Patent Application No. 10-2023-0191516 filed on Dec. 26, 2023, which is hereby incorporated by reference in its entirety.

### BACKGROUND

### Technical Field

The present disclosure relates to a display apparatus for displaying an image.

### Description of Related Art

Display apparatus are applied to various electronic devices such as TVs, mobile phones, laptops, and tablets. To this end, research is continuing to develop display apparatuses that are thinner, lighter, and have lower power consumption.

Among the display devices that display various information using images, an organic light-emission display device (OLED) includes a plurality of pixel areas arranged in a display area where the image is displayed and a plurality of organic light-emitting elements corresponding to the plurality of pixel areas. Since the organic light-emitting element is a self-emitting element that emits light on its own, the organic light-emitting display device has a faster response speed, greater luminous efficiency, and luminance, and a large viewing angle, and superior contrast ratio and color gamut compared to the liquid crystal display device.

Recently, as demand for a head mounted display (HMD) including the organic light-emission display device increases, research on the HMD is increasing. The head-mounted display is an image display device in a form of glasses or a helmet in which a focus is formed at a position close to the user's eyes. The head-mounted display may implement virtual reality (VR) or augmented reality (AR). In the virtual reality (VR) device, the viewer may view a 60-inch sized screen using a 1-inch sized display due to excellent user immersion thereof. For this purpose, the head-mounted display employs a high-resolution organic light-emission display device. However, research is underway on a solution to a problem arising from a small sub-pixel spacing used to implement the high-resolution display.

### SUMMARY

A purpose according to an embodiment of the present disclosure is to provide a display apparatus that may prevent light beams of different colors respectively emitted from adjacent sub-pixels from being mixed with each other.

A purpose according to an embodiment of the present disclosure is to provide a display apparatus in which a plurality of anode electrodes are positioned at different vertical levels such that light beams of different colors respectively emitted from adjacent sub-pixels are prevented from being directed toward adjacent sub-pixels in a viewing angle range and thus from being mixed with each other.

Furthermore, a purpose according to an embodiment of the present disclosure is to provide a display apparatus that may include a sub-pixel that emits white light to improve light efficiency of a light-emitting element.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display apparatus according to one embodiment of the present disclosure includes a substrate having a plurality of sub-pixel areas; a plurality of transistors on the substrate; a planarization layer on the plurality of transistors; a plurality of partitioning patterns on the planarization layer and spaced apart from each other; a plurality of low-reflective metal patterns respectively on the partitioning patterns; a plurality of anode electrodes respectively on the low-reflective metal patterns and the planarization layer, and arranged in a corresponding manner to the plurality of sub-pixel area, respectively; an organic light-emitting layer on the anode electrodes; a cathode electrode on the organic light-emitting layer; and a plurality of color filters on the cathode electrode and corresponding to some sub-pixel areas of the plurality of sub-pixel areas, respectively, wherein a vertical level of an upper surface of at least one color filter among the plurality of color filters is higher than a vertical level of an upper surface of another color filter adjacent to the at least one color filter.

According to one embodiment of the present disclosure, the organic light-emitting layer emits white light. The sub-pixels include a sub-pixel emitting white light, and sub-pixels emitting red light, green light, and blue light, respectively. Thus, light extraction efficiency may be improved.

Furthermore, according to one embodiment of the present disclosure, the plurality of anode electrodes are positioned at different vertical levels such that light beams of different colors respectively emitted from adjacent sub-pixels are prevented from being directed toward adjacent sub-pixels in a viewing angle range and thus from being mixed with each other, and the color may be prevented from being viewed in a distorted manner.

Furthermore, according to an embodiment of the present disclosure, the plurality of color filters corresponding to the plurality of sub-pixels may be formed to have a uniform thickness, thereby preventing color differences from occurring in the viewing angle range.

Furthermore, as the light extraction efficiency of the display apparatus is improved, the display apparatus may operate at low power. As a result, the power consumption of the display apparatus may be reduced.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF DRAWINGS

FIG. 1 is a schematic plan view of a display apparatus according to an embodiment of the present disclosure.

FIG. 2 is a cross-sectional view taken along a line 2-2 in FIG. 1 according to an embodiment of the present disclosure.

FIG. 3 is a schematic plan view of a display apparatus according to another embodiment of the present disclosure.

FIG. 4 is a cross-sectional view taken along a line 4-4 in FIG. 3 according to an embodiment of the present disclosure.

FIGS. 5 to 15 are diagrams for illustrating a method for manufacturing a display apparatus according to another embodiment of the present disclosure.

FIG. 16 is a schematic perspective view of a head mounted device including a display apparatus according to an embodiment of the present disclosure.

FIG. 17 is a top view showing a head mounted device implementing virtual reality according to an embodiment of the present disclosure.

FIG. 18 is a side view showing a head mounted device that implements augmented reality according to an embodiment of the present disclosure . . .

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and embodiments of the present disclosure are not limited thereto.

The terminology used herein is directed to the purpose of describing particular embodiments only and is not intended to be limiting to the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected with” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

It will be understood that when an element or layer is referred to as being “connected to”, or “connected with” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display apparatus according to each embodiment of the present disclosure will be described with reference to the attached drawings.

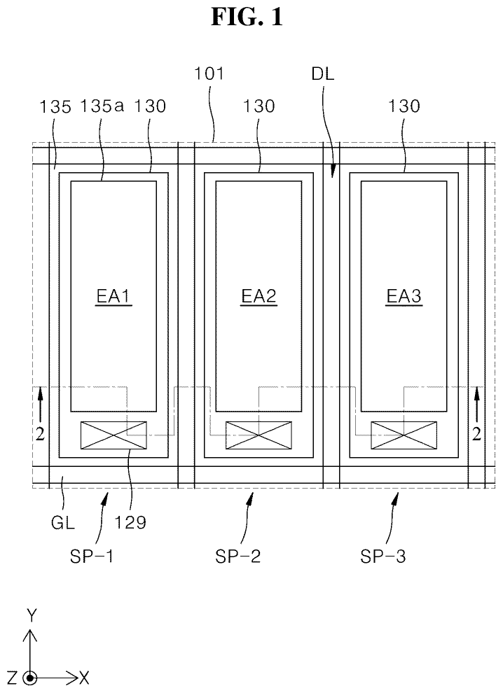

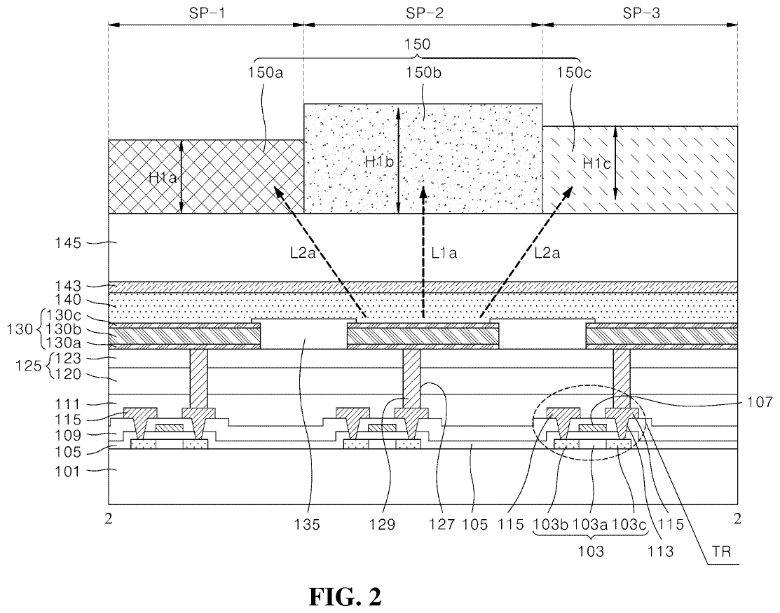

FIG. 1 is a schematic plan view of a display apparatus according to an embodiment of the present disclosure. FIG. 2 is a cross-sectional view taken along a line 2-2 in FIG. 1 according to an embodiment of the present disclosure. For convenience of illustration, FIG. 1 and FIG. 2 show only three sub-pixels SP-1, SP-2, and SP-3.

Referring to FIG. 1 and FIG. 2, a plurality of data lines DL and a plurality of gate lines GL may be disposed on a display area of a substrate 101. The plurality of data lines DL may intersect the plurality of gate lines GL. A sub-pixel area is defined by the data line DL and the gate line SL intersecting each other. A plurality of sub-pixels SP-1, SP-2, and SP-3 may be disposed on the display area of the substrate. For example, one sub-pixel may be electrically connected to one gate line and one data line.

The plurality of sub-pixels SP-1, SP-2, and SP-3 disposed on the display area of the substrate 101 may be arranged in a matrix manner (M*N, where M and N are natural numbers). The plurality of sub-pixels SP-1, SP-2, and SP-3 may be arranged in the matrix manner along a first direction of the substrate 101 and a second direction intersecting the first direction thereof. In this regard, the first direction may be an X-axis direction or a row direction, and the second direction may be a Y-axis direction or a column direction. However, embodiments of the present disclosure are not limited to thereto, and an arrangement order and direction of the sub-pixels SP-1, SP-2, and SP-3 may vary in various ways.

A plurality of light-emission areas EA1, EA2, and EA3 may be arranged in a corresponding manner to the sub-pixels SP-1, SP-2, and SP-3, respectively. The first light-emission area EA1 may be located in the first sub-pixel SP-1, the second light-emission area EA2 may be located in the second sub-pixel SP-2, and the third light-emission area EA3 may be located in the third sub-pixel SP-3.

A plurality of color filters 150a, 150b, and 150c may be arranged in a corresponding manner to the plurality of sub-pixel SP-1, SP-2, and SP-3, respectively. The plurality of color filters 150a, 150b, and 150c may include the first color filter 150a, the second color filter 150b, and the third color filter 150c. The plurality of color filters 150a, 150b, and 150c may have different colors. For example, the first color filter 150a may have a red color, the second color filter 150b may have a green color, and the third color filter 150c may have a blue color.

The plurality of sub-pixel SP-1, SP-2, and SP-3 may emit light beams of different colors to the light-emission areas EA1, EA2, and EA3 through the respective color filters 150a, 150b, and 150c, respectively. For example, the first sub-pixel SP-1 may emit red light, the second sub-pixel SP-2 may emit green light, and the third sub-pixel SP3 may emit blue light.

The plurality of light-emission areas EA1, EA2, and EA3 are defined by a bank 135 having a bank hole 135a defined therein. The bank hole 135a may be an opening that exposes each of the light-emission areas EA1, EA2, and EA3. In other words, the areas not covered with the bank 135 so as to be exposed may be the plurality of light-emission areas EA1, EA2, and EA3, respectively.

A plurality of anode electrodes 130 may be arranged in a corresponding manner to the plurality of sub-pixel SP-1, SP-2, and SP-3, respectively. The plurality of anode electrodes 130 may be arranged to be spaced apart from each other.

A portion of the anode electrode 130 exposed through the bank hole 135a of the bank 135 may be defined as the light-emission area. For example, the first light-emission area EA1 may be defined by the bank hole 135a in the first sub-pixel SP-1. The second light-emission area EA2 may be defined by the bank hole 135a in the second sub-pixel SP-2. The third light-emission area EA3 may be defined by the bank hole 135a in the third sub-pixel SP-3.

The anode electrode 130 of each of the plurality of sub-pixels SP-1, SP-2, and SP-3 may be connected to at least one transistor disposed on the substrate 101 via each contact area 129 (which may correspond to a contact electrode). This will be described below with reference to FIG. 2.

A display apparatus according to an embodiment of the present disclosure may operate in either a top emission scheme or a bottom emission scheme, depending on a direction in which the light emitted from the light-emitting layer is emitted. Hereinafter, the top emission scheme will be described by way of example.

Referring to FIG. 2, a transistor TR may be disposed on the substrate 101. The substrate 101 may include a silicon wafer. In one embodiment, the substrate 101 may include glass or plastic.

On the substrate 101, a driver circuit including various signal lines, transistors and a capacitor may be disposed in each of the sub-pixels SP-1, SP-2, and SP-3. The signal lines may include a gate line GL, a data line DL, a power line, and a reference line, and the transistors TR may include a switching transistor and a driving transistor. For example, the switching transistor and the driving transistor may be formed on the substrate 101 using a CMOS (Complementary Metal Oxide Semiconductor) process.

The switching transistor switches based on a gate signal supplied to the gate line to supply a data voltage supplied from the data line to the driving transistor, and plays the role of select the sub-pixel SP-1, SP-2, or SP-3. The driving transistor serves to drive the light-emitting element by supplying power to the anode electrode of the sub-pixel SP-1, SP-2, or SP-3 selected from the switching transistor.

The capacitor serves to maintain the data voltage supplied to the driving transistor for one frame, and electrodes of the capacitor may be electrically connected to the driving transistor.

The transistor TR may include a semiconductor layer 103, a gate insulating layer 105, a gate electrode 107, and a source/drain electrode 115. The gate insulating layer 105 may be disposed between the semiconductor layer 103 and the gate electrode 107. An insulating layer that reduces or prevents penetration of moisture or impurities may be further included between the substrate 101 and the semiconductor layer 103.

The semiconductor layer 103 may be made of an oxide semiconductor or silicon-based semiconductor material. For example, the semiconductor layer 103 may include a transparent oxide semiconductor material such as indium gallium zinc oxide (IGZO) or indium zinc oxide: (IZO). Furthermore, the semiconductor layer 103 may include polysilicon semiconductor material.

The semiconductor layer 103 may include a channel area 103a, a source area 103b, and a drain area 103c. The gate insulating layer 105 may be composed of a single layer or a stack of a plurality of layers made of silicon oxide (SiOx) or silicon nitride (SiNx).

The gate electrode 107 may be disposed on the gate insulating layer 105. An area of the semiconductor layer 103 that overlaps the gate electrode 107 in a vertical direction may be the channel area 103a. The source area 103b and the drain area 103c may be disposed on both opposing sides of the channel area 103a, respectively.

An interlayer insulating layer 109 and a passivation layer 111 may be sequentially disposed on the gate electrode 107. The source/drain electrode 115 may be disposed to fill a contact hole extending through the interlayer insulating layer 109, the passivation layer 111, and the gate insulating layer 105. The source/drain electrode 115 may be disposed on both opposing sides of the gate electrode 107 disposed therebetween and may be connected to the source area 103b and the drain area 103c of the semiconductor layer 103, respectively.

A planarization layer 125 may be disposed on the passivation layer 111 and the source/drain electrode 115. The planarization layer 125 may include a first planarization layer 120 and a second planarization layer 123. The planarization layer 125 serves to planarize a step formed due to the underlying circuit element including the driving transistor TR.

The planarization layer 125 may have a pixel contact hole 127 defined therein extending through the first planarization layer 120 and the second planarization layer 123 while exposing a portion of a surface of the source/drain electrode 115 of the driving transistor TR. The pixel contact electrode 129 may fill the pixel contact hole 127 while one surface thereof is in contact with the source/drain electrode 115.

The anode electrode 130 may be disposed on the second planarization layer 123. In one embodiment, the anode electrode 130 may have a multilayer structure. For example, the anode electrode 130 may have a structure in which a lower anode electrode 130a, a middle anode electrode 130b, and an upper anode electrode 130c are stacked in this order. The middle anode electrode 130b may be disposed between the lower anode electrode 130a and the upper anode electrode 130c. The middle anode electrode 130b may have a second thickness that is different from a first thickness of each of the lower anode electrode 130a and the upper anode electrode 130c. For example, the first thickness may be smaller than the second thickness. The lower anode electrode 130a and the upper anode electrode 130c may have the same thickness. However, embodiments of the present disclosure are not limited thereto.

The anode electrode 130 may include a transparent metal oxide such as Indium-Tin-Oxide (ITO) or Indium-Zinc-Oxide (IZO). Alternatively, the anode electrode 130 may have a single-layer or a multi-layer structure including a reflective metal film made of silver (Ag), aluminum (Al), gold (Au), nickel (Ni), chromium (Cr), or a combination thereof. The anode electrode 130 may be referred to as a pixel electrode.

The bank 135 may be disposed on the second planarization layer 123. The bank 135 serves to distinguish the sub-pixels SP-1, SP-2, and SP-3 from each other. To this end, the bank 135 may be formed to cover an edge of the anode electrode 130. Furthermore, each of the light-emission areas EA1, EA2, and EA3 may be exposed through the bank hole 135a of the bank 135 (see FIG. 1). That is, the bank hole 135a of the bank 135 may define each of the light-emission areas EA1, EA2, and EA3. Furthermore, the bank 135 may prevent light beams of different colors respectively output from adjacent sub-pixels from being mixed with each other. The bank 135 may include an organic insulating film made of polyimide and epoxy. In one example, the bank 135 may include one of black resin, graphite, or black ink.

An organic light-emitting layer 140 may be disposed on the anode electrode 130. In one example, the organic light-emitting layer 140 may include an organic material that emits white light.

The organic light-emitting layer 140 may include a stack structure in which a hole transport layer HTL, a light-emitting layer EML, an electron transport layer ETL, a hole blocking layer HBL, a hole injecting layer HIL, an electron blocking layer EBL, and an electron injecting layer EIL are stacked.

A cathode electrode 143 may be disposed on the organic light-emitting layer 140. The cathode electrode 143 may be embodied as a common layer commonly formed across the plurality of sub-pixels SP-1, SP-2, and SP-3. The cathode electrode 143 may be referred to as a common electrode or a second electrode. The cathode electrode 143 may include a semi-transmissive metal material. For example, the cathode electrode 143 may include magnesium (Mg), silver (Ag), or an alloy of magnesium (Mg) and silver (Ag).

A light-emitting element may be configured to include the anode electrode 130, the organic light-emitting layer 140, and the cathode electrode 143.

An encapsulation layer 145 may be disposed on the cathode electrode 143. The encapsulation layer 145 may seal the transistor DR and the light-emitting element disposed thereunder. The encapsulation layer 145 may include, but is not limited to, an organic insulating material.

A color filter 150 may be disposed on the encapsulation layer 145. The color filter 150 may be positioned in a corresponding manner to each of the plurality of sub-pixels SP-1, SP-2, and SP-3. The color filter 150 may include the first color filter 150a, the second color filter 150b, and the third color filter 150c. The first color filter 150a using a red pigment may be located in a corresponding manner to the first sub-pixel SP-1. The second color filter 150b using a green pigment may be located in a corresponding manner to the second sub-pixel SP-2. The third color filter 150c using a blue pigment may be located in a corresponding manner to the third sub-pixel SP-3.

In one example, the plurality of color filters 150a, 150b, and 150c disposed on the encapsulation layer 145 may be sequentially formed according to colors thereof. For example, first, a red first color filter 150a may be formed, then a blue third color filter 150c may be formed, and then, a green second color filter 150b may be formed.

The first color filter 150a may have a first thickness H1a, the second color filter 150b may have a second thickness H1b, and the third color filter 150c may have a third thickness H1c. The first thickness H1a of the first color filter 150a may be smallest, and the second thickness H1b of the second color filter 150b may be largest.

In a process of sequentially forming the plurality of color filters 150a, 150b, and 150c according to the colors thereof, it may be difficult to control the thicknesses H1a, H1b, and H1c and line widths CD of the first color filter 150a, the second color filter 150b, and the third color filter 150c to be uniform. As the process proceeds, a thickness of the color filter becomes larger. Thus, the second thickness H1b of the second color filter 150b formed in the last order may be largest.

Furthermore, in the process of forming the color filters, the line width of each of the color filters 150a, 150b, and 150c may decrease. For example, the line width of each of the first color filter 150a, the second color filter 150b, and the third color filter 150c may be reduced to a size smaller than an area size of the bank hole 135a (see FIG. 1).

As the line width of color filters 150a, 150b, and 150c is reduced to a size smaller than the area size of the bank hole 135a (see FIG. 1), this may cause light leakage. For example, the light leakage may occur in which a light beam L2a emitted in a viewing angle range among light beams L1a and L2a emitted from the organic light-emitting layer 140 of the second sub-pixel SP-2 is directed to the neighboring first and third sub-pixels SP-1 and SP3. Accordingly, colors of light beams respectively emitted from neighboring sub-pixels may be mixed with each other.

Furthermore, as the first to third color filters 150a, 150b, and 150c are formed to have different thicknesses H1a, H1b, and H1c, the color may be viewed in a distorted manner in the viewing angle range of the viewer. The viewing angle range may be defined as the maximum angle range in which an image quality of the image displayed on the display apparatus may be viewed without distortion, such as darkening or blurring of the color at a left or right side or at a top or bottom side. As the viewing angle related performance of the display apparatus is better, the viewer may recognize the screen at the same image quality level as an image quality level when viewing the screen at a central position of the range even when viewing the screen at a left or right side or at a top or bottom side of the range. When the color is viewed in a distorted manner in the viewing angle range, the screen with the distorted color may be provided such that image quality may deteriorate. Furthermore, when light leakage occurs, uniform luminance cannot be provided such that the image quality may deteriorate.

Accordingly, in another embodiment of the present disclosure, a structure that may prevent or at least reduce light leakage and color distortion in the viewing angle range is described.

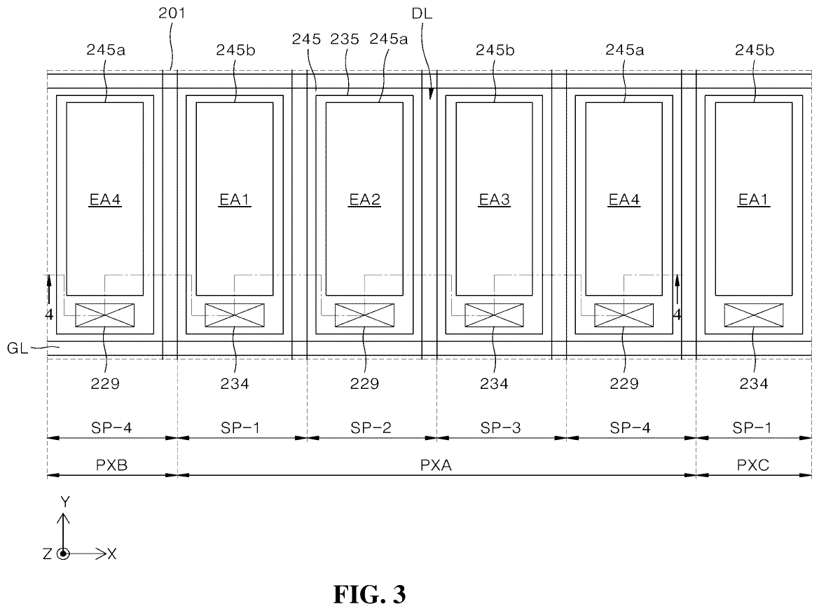

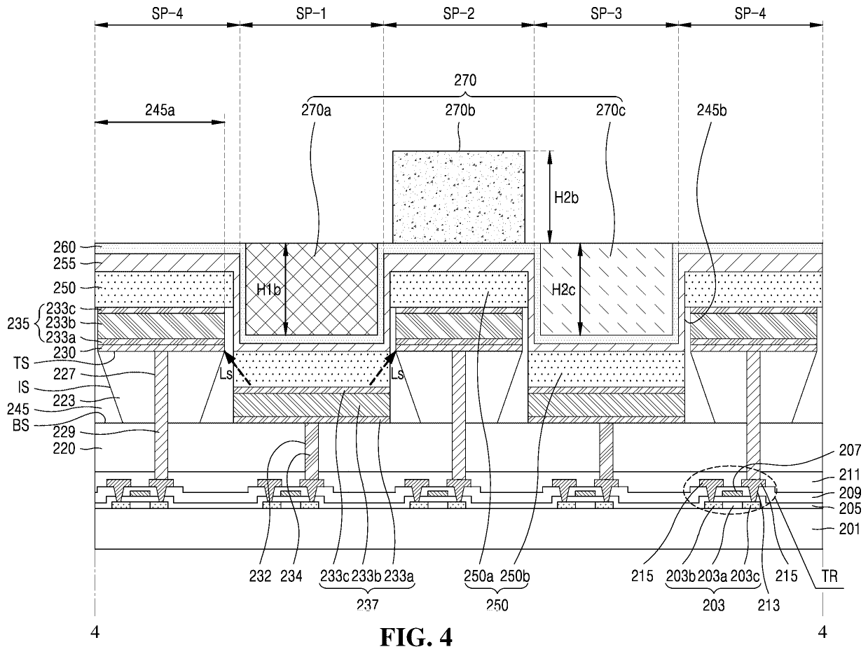

FIG. 3 is a schematic plan view of a display apparatus according to another embodiment of the present disclosure. FIG. 4 is a cross-sectional view taken along a line 4-4 in FIG. 3 according to an embodiment of the present disclosure.

Referring to FIG. 3 and FIG. 4, the data lines DL and the gate lines GL disposed on a display area of a substrate 201 may be arranged to intersect each other to define respective areas of the plurality of sub-pixels SP-1, SP-2, SP-3, and SP-4. The plurality of sub-pixel SP-1, SP-2, SP-3, and SP-4 may be arranged in a matrix manner along the first direction (e.g., X-axis direction or row direction) of the substrate 201 and the second direction (e.g., Y-axis direction or column direction). In this regard, the first direction may be the row direction, and the second direction may be the column direction. However, the arrangement order and direction of the sub-pixels SP-1, SP-2, SP-3, and SP-4 may vary in various ways.

The sub-pixel may be configured to include a light-emitting element and a transistor for driving the light-emitting element. One unit pixel may be configured to include at least three or more sub-pixels arranged adjacent to each other. In another embodiment of the present disclosure, the first sub-pixel SP-1, the second sub-pixel SP-2, the third sub-pixel SP-3, and the fourth sub-pixel SP-4 may be arranged to be adjacent to each other to constitute one unit pixel PXA. One unit pixel PXA may be disposed adjacent to other unit pixels PXB and PXC. The first sub-pixel SP-1, the second sub-pixel SP-2, the third sub-pixel SP-3, and the fourth sub-pixel SP-4 may emit green, blue, red, and white light beams, respectively. In embodiment of the present disclosure, the fourth sub-pixel SP-4 that emits white light may be included to improve light efficiency.

The plurality of light-emission areas EA1, EA2, EA3, and EA4 may be located in a corresponding manner to the sub-pixels SP-1, SP-2, SP-3, and SP-4, respectively. The first light-emission area EA1 may be located in the first sub-pixel SP-1, the second light-emission area EA2 may be located in the second sub-pixel SP-2, the third light-emission area EA3 may be located in the third sub-pixel SP-3, and the fourth light-emission area EA4 may be located in the fourth sub-pixel SP-4.

First to third color filters 270a, 270b, and 270c may be disposed in a corresponding manner to the first to third sub-pixels SP-1, SP-2, and SP-3, respectively. The color filter corresponding to the fourth sub-pixel SP-4 is not disposed. The plurality of color filters 270a, 270b, and 270c may include the first color filter 270a, the second color filter 270b, and the third color filter 270c. The first to third color filters 270a, 270b, and 270c may have different colors. For example, the first color filter 270a may have red, the second color filter 270b may have green, and the third color filter 270c may have blue.

The first to third sub-pixels SP-1, SP-2, and SP-3 may emit light beams of different colors to the light-emission areas EA1, EA2, and EA3 through the first to third color filters 270a, 270b, and 270c, respectively. For example, the first sub-pixel SP-1 may emit red light, the second sub-pixel SP-2 may emit green light, and the third sub-pixel SP-3 may emit blue light. Further, white light may be emitted from the fourth sub-pixel SP-4 where the color filter is not disposed.

Each of the plurality of light-emission areas EA1, EA2, EA3, and EA4 may be defined by a bank 245 in which bank holes 245a and 245b (see FIG. 3) are defined. The bank holes 245a and 245b may be openings that expose the light-emission areas EA1, EA2, EA3, and EA4. The bank holes 245a and 245b may include the first bank hole 245a and the second bank hole 245b.

A plurality of anode electrodes 237 and 235 may be disposed in a corresponding manner to the plurality of sub-pixel SP-1, SP-2, SP-3, and SP-4, respectively. The plurality of anode electrodes 237 and 235 may be arranged to be spaced apart from each other.

Each of the anode electrodes 237 and 235 of the plurality of sub-pixel SP-1, SP-2, SP-3, and SP-4 may be connected to the transistor disposed on the substrate 201 via each of contact electrodes 229 and 234. This will be described below with reference to FIG. 4.

Referring to FIG. 4 along with FIG. 3, a plurality of transistors TR may be disposed on the substrate 201. The substrate 201 may include a silicon wafer. In one embodiment, the substrate 201 may include glass or plastic.

On the substrate 201, the sub-pixel SP-1, SP-2, SP-3, and SP-4 may be arranged. Each of the sub-pixel SP-1, SP-2, SP-3, and SP-4 may be configured to include a light-emitting element and a driver circuit for driving the same. The driver circuit may include a plurality of transistors, a capacitor and signal lines. The plurality of transistors TR may include a driving transistor and a switching transistor. In one example, each of the plurality of transistors may be formed on the substrate 201 using a CMOS process. In the present disclosure, the transistor TR as the driving transistor is described by way of example. The same components as those of the driving transistor may also be included in the switching transistor. The plurality of transistors TR may be arranged to drive the plurality of sub-pixels SP-1, SP-2, SP-3, and SP-4 arranged along the first direction (e.g., X-axis direction or row direction) and the second direction (e.g., Y-axis direction or column direction) intersecting the first direction of the substrate 201. Accordingly, the plurality of transistors TR may be arranged along the first direction (e.g., X-axis direction or row direction) and the second direction (e.g., Y-axis direction or column direction) intersecting the first direction. In other words, the plurality of transistors TR may include transistors located in even-numbered columns and transistors located in odd-numbered columns.

The transistor TR may include a semiconductor layer 203, a gate insulating layer 205, a gate electrode 207, and a source/drain electrode 215. The gate insulating layer 205 may be disposed between the semiconductor layer 203 and the gate electrode 207. The semiconductor layer 203 may include a channel area 203a, a source area 203b, and a drain area 203c. On the gate insulating layer 205, the gate electrode 207 may be disposed so as to overlap the channel area 203a. The source area 203b and the drain area 203c may be respectively disposed on both opposing sides of the channel area 203a.

An interlayer insulating layer 209 may be disposed to cover the gate electrode 207. The passivation layer 211 may be disposed on the interlayer insulating layer 205. A source/drain electrode 215 may be disposed to fill a contact hole 213 extending through the interlayer insulating layer 209, the passivation layer 211, and the gate insulating layer 209. The source/drain electrodes 215 may be respectively disposed on both opposing sides of the gate electrode 207 disposed therebetween, and may be electrically connected to the source area 203b and the drain area 203c, respectively.

A planarization layer 220 may be disposed on the passivation layer 211 and the source/drain electrode 215. The planarization layer 220 planarizes a step formed due to the underlying circuit element including the transistor TR.

A plurality of partitioning patterns 223 may be disposed on the planarization layer 220. The plurality of partitioning pattern 223 may be arranged to be spaced apart from each other. The partitioning pattern 223 may be disposed on top of the transistor TR and may be positioned so that at least a portion thereof overlaps the transistor TR.

In one example, the partitioning pattern 223 may be located on top of the transistor TR located in the even-numbered column among the plurality of transistors TR. However, embodiments of the present disclosure are not limited thereto. In another example, the partitioning pattern 223 may be located on top of the transistor TR located in the odd-numbered column. In this regard, the plurality of partitioning pattern 223 may be arranged in selected one of the even-numbered column or the odd-numbered column. For example, when the plurality of partitioning patterns 223 are respectively disposed in a corresponding manner to and on top of the transistors TR located in the even-numbered columns, the transistor TR may not be located on top of the transistor disposed in the odd-numbered column. Accordingly, the partitioning pattern 223 may be disposed on top of the transistor TR located in each of the even-numbered columns disposed respectively on both opposing sides of the transistor TR located in the odd-numbered column.

In another example, when the plurality of partitioning patterns 223 are respectively disposed in a corresponding manner to and on top of the transistors TR located in the odd-numbered columns, the transistor TR may not be located on top of the transistor disposed in the even-numbered column. Accordingly, the partitioning pattern 223 may be disposed on top of the transistor TR located in each of the odd-numbered columns disposed respectively on both opposing sides of the transistor TR located in the even-numbered column. In the present disclosure, for convenience of description, a case in which the plurality of partitioning patterns 223 are respectively disposed in a corresponding manner to and on top of the transistors TR located in the even-numbered columns is described. However, embodiments of the present disclosure are not limited thereto.

The partitioning pattern 223 may have a reverse taper shape. For example, a width of an upper surface TS of each partitioning pattern 223 may be larger than a width of a lower surface BS thereof. A side surface IS extending between the upper surface TS and the lower surface BS of the partitioning pattern 223 may be an inclined surface with respect to a horizontal plane.

The first pixel contact electrode 229 may extend through the partitioning pattern 223 so as to be in contact with the source/drain electrode 215 of the transistor TR. The first pixel contact electrode 229 may fill a first pixel contact hole 227 extending through the partitioning pattern 223, the planarization layer 220, and the first passivation layer 211.

A low-reflective metal pattern 230 is disposed on the upper surface TS of the partitioning pattern 223 so that one surface of the low-reflective metal pattern 230 may contact the first pixel contact electrode 229. The low-reflective metal pattern 230 may include a low-reflective metal material. The low-reflective metal material may include a material with a relatively lower reflectance than that of aluminum used as a reflective material. For example, the low-reflective metal material may include tungsten oxide (WOx), chromium (Cr), molybdenum (Mo), molybdenum-tungsten alloy (MoW), or titanium (Ti) which has relatively low reflectivity but excellent conductivity. In one embodiment, the first pixel contact electrode 229 and the low-reflective metal pattern 230 may include the same material.

A first anode electrode 235 electrically connected to the source/drain electrode 215 of the transistor TR located in the even-numbered column may be disposed on the low-reflective metal pattern 230. The first anode electrode 235 may have a multilayer structure. For example, the first anode electrode 235 may have a structure in which a lower anode electrode 233a, a middle anode electrode 233b, and an upper anode electrode 233c are sequentially stacked.

The second anode electrode 237 which is electrically connected to the source/drain electrode 215 of the transistor TR located in the odd-numbered columns may be disposed on the planarization layer 220. The second anode electrode 237 may have a multilayer structure. For example, the second anode electrode 237 may have a structure in which the lower anode electrode 233a, the middle anode electrode 233b, and the upper anode electrode 233c are sequentially stacked. A portion of the lower anode electrode 233a of the second anode electrode 237 may contact the second pixel contact electrode 234 that contacts one surface of the source/drain electrode 215 exposed through a second pixel contact hole 232.

The upper surfaces of the first anode electrode 235 and the second anode electrode 237 may be positioned at different vertical levels. For example, the upper surface of the second anode electrode 237 may be positioned at a lower vertical level than a vertical level of the upper surface of the first anode electrode 235.

The bank 245 may be disposed to cover a side surface of each of the first and second anode electrodes 235 and 237. The bank 245 may cover the side surface of each of the first and second anode electrodes 235 and 237, so that a side surface of each of the lower anode electrode 233a, the middle anode electrode 233b, and the upper anode electrode 233c may not be exposed to an outside.

The bank 245 may include an inner side surface and an outer side surface opposite the inner side surface.

The inner side surface of the bank 245 may be in contact with the side surface of the first anode electrode 235 and a side surface IS of the partitioning pattern 223, while the outer side surface of the bank 245 may be in contact with the side surface of the second anode electrode 237.

As shown in FIG. 3 and FIG. 4, the bank 245 may include the first bank hole 245a and the second bank hole 245b as the openings that expose light-emission areas EA1, EA2, EA3, and EA4. The first bank hole 245a may expose the upper anode electrode 233c of the first anode electrode 235. The upper anode electrode 233c exposed through the first bank hole 245a may be the upper surface of the first anode electrode 235. The second bank hole 245b located between the neighboring first bank holes 245a may have a trench shape having the upper surface of the upper anode electrode 233c as the uppermost portion of the second anode electrode 237 as a bottom surface thereof, and the outer side surface of the bank 245 as a side wall thereof extending from the bottom surface.

An organic light-emitting layer 250 may be disposed on the first anode electrode 235 and the second anode electrode 237. The organic light-emitting layer 250 may include a first organic light-emitting layer 250a disposed on the first anode electrode 235 and a second organic light-emitting layer 250b disposed on the second anode electrode 237. In one example, each of the first and second organic light-emitting layers 250a and 250b may include an organic material that emits white light.

The upper surfaces of the first and second organic light-emitting layers 250a and 250b may have different vertical levels. For example, the upper surface of the first organic light-emitting layer 250a disposed on the first anode electrode 235 may be positioned at a higher vertical level than a vertical level of the upper surface of the second organic light-emitting layer 250b disposed on the second anode electrode 237. In particular, the second organic light-emitting layer 250b may be disposed at a lower vertical level than a vertical level of the low-reflective metal pattern 230 of the first anode electrode 235. Accordingly, the first organic light-emitting layer 250a and the second organic light-emitting layer 250b may be positioned at different vertical levels and thus be separate layers spaced from each other.

Accordingly, light emitted from the light-emitting element located in the odd-numbered column so as to be directed toward the viewing angle range may reach and be reflected from the low-reflective metal pattern 230 positioned at a higher vertical level that that of the second organic light-emitting layer 250b. Accordingly, the light leakage that the light emitted from the light-emitting element located in the odd-numbered column so as to be directed toward the viewing angle range transmits into the sub-pixels of the light-emitting elements respectively located in the even-numbered columns adjacent to the odd-numbered column may be prevented.

A cathode electrode 255 may be disposed on the first organic light-emitting layer 250a and the second organic light-emitting layer 250b. The cathode electrode 255 may be formed in a concave-convex shape in a conformal manner to a profile of a combination of the first organic light-emitting layer 250a and the second organic light-emitting layer 250b and may extend in a continuous manner over an entire surface of the substrate 201.

The light-emitting element may be configured to include each of the anode electrodes 235 and 237, the organic light-emitting layer 250, and the cathode electrode 255. When voltage is applied to the electrodes, light may be emitted from the light-emission area under recombination of holes injected from the anode electrode 235 or 237 and electrons injected from the cathode electrode 255.

A second passivation layer 260 including an insulating material may be disposed on the cathode electrode 255.

As the second passivation layer 260 is formed along a profile of the cathode electrode 255, the second passivation layer 260 may have a concave-convex shape.

A color filter 270 may be disposed on the second passivation layer 260. The color filter 270 may be disposed in a corresponding manner to each of the plurality of sub-pixels SP-1, SP-2, and SP-3 except for the fourth sub-pixel SP-4.

The color filter 270 may include a first color filter 270a, a second color filter 270b, and a third color filter 270c. The first color filter 270a may emit red light, the second color filter 270b may emit green light, and the third color filter 270c may emit blue light. Since the color filter is not disposed in a corresponding manner to the fourth sub-pixel SP-4, the white light emitted from the organic light-emitting layer 250 in the fourth sub-pixel may be emitted to the outside.

The first color filter 270a may have a first thickness, the second color filter 270b may have a second thickness, and the third color filter 270c may have a third thickness.

Each of the first and third color filters 270a and 270c may be positioned to fill the second bank hole 245b having a trench shape. Each of the first and third color filters 270a and 270c may have a thickness equal to a depth of the trench. Accordingly, the first thickness of the first color filter 270a and the third thickness of the third color filter 270c may be equal to each other. That is, the first and third color filters 270a and 270c may have the same thickness and may fill the respective second bank holes 245b having the trench shape, and thus may have the same line width. Further, the first to third color filters 270a to 270c may have the same thickness and the same line width. Further, each of the first and third color filters 270a and 270c may have thicknesses such that an upper surface thereof is coplanar with an upper surface of the second passivation layer 260.

Accordingly, the color distortion in which the thicknesses of the color filters are different from each other, and thus the color is viewed in the distorted manner in the viewing angle range may be prevented. Furthermore, the light leakage caused by the reduction in the line width of the color filter may be prevented.

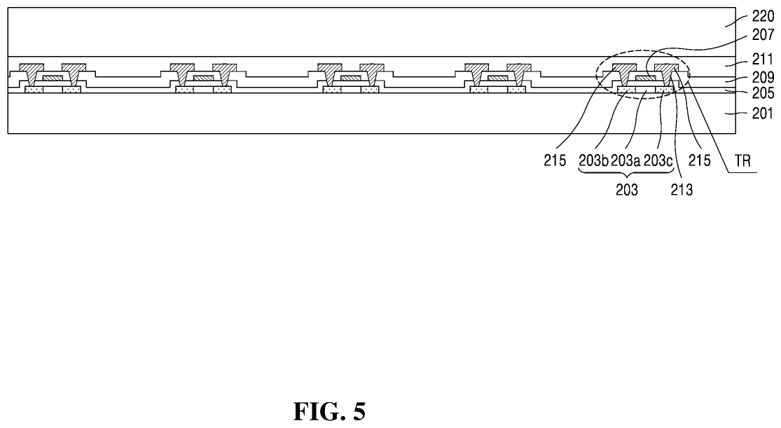

FIG. 5 to FIG. 15 are cross-sectional views for illustrating a method for manufacturing a display apparatus according to another embodiment of the present disclosure. In particular, FIG. 5 to FIG. 15 are cross-sectional views of intermediate structures corresponding to intermediate steps of the method for manufacturing the display apparatus of FIG. 4, and thus, the same reference numerals as those in FIG. 4 may indicate the same components in FIG. 5 to FIG. 15.

Referring to FIG. 5, the plurality of transistors TR may be disposed on the substrate 201. The substrate 101 may include a silicon wafer. In one embodiment, the substrate 101 may include glass or plastic.

Each transistor TR may include the semiconductor layer 203, the gate insulating layer 205, the gate electrode 207, and the source/drain electrode 215. The gate insulating layer 205 may be disposed between the semiconductor layer 203 and the gate electrode 207. The semiconductor layer 203 may include the channel area 203a, the source area 203b, and the drain area 203c. On the gate insulating layer 205, the gate electrode 207 may be disposed so as to vertically overlap the channel area 203a. The source area 203b and the drain area 203c may be respectively disposed on both opposing sides of the channel area 203a.

The drain area 203c of the transistor TR may be in contact with the source/drain electrode 215 that fills the contact hole extending through the interlayer insulation layer 209, the first passivation layer 211, and the gate insulation layer 209.

The planarization layer 220 may be disposed on the first passivation layer 211 and the source/drain electrodes 215. The planarization layer 220 serves to planarize the step formed due to the underlying circuit element including the transistor TR. The planarization layer 220 may include an organic insulating material such as acryl resin, epoxy resin, phenolic resin, polyamide resin, or polyimide resin. However, embodiments of the present disclosure are not limited thereto.

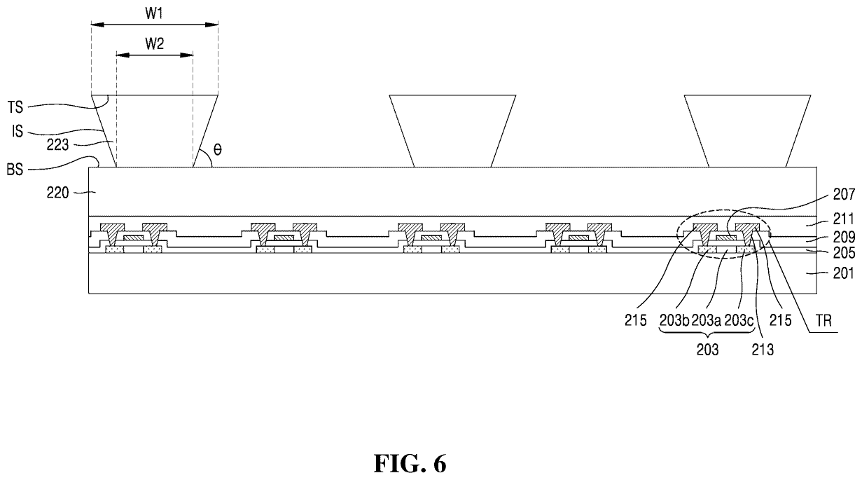

Referring to FIG. 6, the plurality of partitioning pattern 223 is formed on the planarization layer 220. A width W1 of the upper surface TS of each of the partitioning patterns 223 may be larger than a width W2 of the lower surface BS thereof. Accordingly, the side surface IS of the partitioning pattern 223 may be inclined at an angle θ smaller than 90 degrees with respect to a horizontal plane. The side surface IS of partitioning pattern 223 may extend in an inclined manner with respect to the horizontal plane. That is, the partitioning pattern 223 may have a reverse taper shape.

The partitioning pattern 223 may be disposed on top of the transistor TR and may be positioned so that at least a portion thereof overlaps the transistor TR. According to an embodiment of the present disclosure, the plurality of partitioning patterns 223 may be respectively disposed in a corresponding manner to and on top of the transistors TR located in the even-numbered columns. Thus, the transistor TR may not be located on top of the transistor disposed in the odd-numbered column. Accordingly, the partitioning pattern 223 may be disposed on top of the transistor TR located in each of the even-numbered columns disposed respectively on both opposing sides of the transistor TR located in the odd-numbered column. However, embodiments of the present disclosure are not limited thereto. In one example, the partitioning pattern 223 may include the same organic insulating material as that of the planarization layer 220.

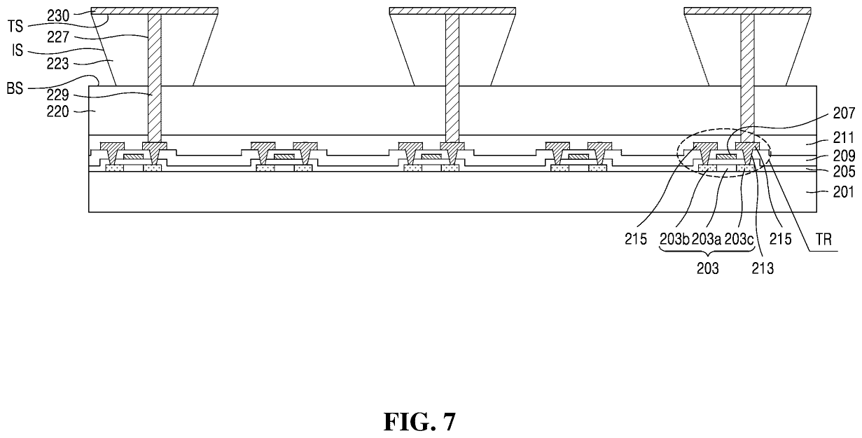

Referring to FIG. 7, the first pixel contact electrode 229 is formed. To this end, first, the first pixel contact hole 227 extending through the partitioning pattern 223, the planarization layer 220, and the first passivation layer 211 may be formed. The first pixel contact hole 227 may expose a surface of the source/drain electrode 215.

The first pixel contact electrode 229 may be formed to fill the first pixel contact hole 227. One surface of the first pixel contact electrode 229 may contact one surface of the source/drain electrode 215 exposed through the first pixel contact hole 227. The other surface opposite to one surface of the first pixel contact electrode 229 may be in contact with the lower surface of the low-reflective metal pattern 230. The low-reflective metal pattern 230 may be disposed on the upper surface TS of the partitioning pattern 223. The end of the low-reflective metal pattern 230 may be aligned with the end of the partitioning pattern 223. To this end, the low-reflective metal layer may be formed on an entire surface of the substrate 201, and then an etching process may be performed so that the low-reflective metal pattern 230 remains only on the partitioning pattern 223 and a remaining portion thereof is removed.

The low-reflective metal pattern 230 may include a low-reflective metal material. The low-reflective metal material may include a material with a relatively lower reflectance than that of aluminum used as a reflective material. For example, the low-reflective metal material may include tungsten oxide (WOx), chromium (Cr), molybdenum (Mo), molybdenum-tungsten alloy (MoW), or titanium (Ti) which has relatively low reflectivity but excellent conductivity.

The low-reflective metal pattern 230 and the first pixel contact electrode 229 may be formed in the same process. In another example, the low-reflective metal pattern 230 and the first pixel contact electrode 229 may be formed in different processes. The low-reflective metal pattern 230 and the first pixel contact electrode 229 may be made of the same material.

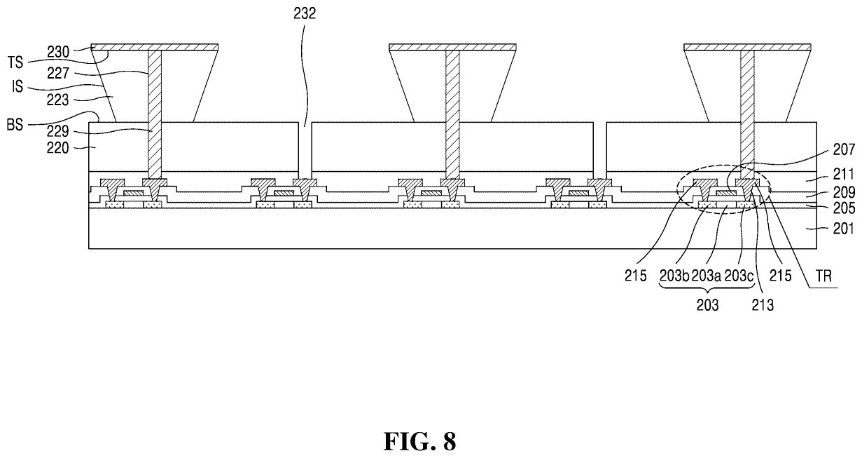

Referring to FIG. 8, the second pixel contact hole 232 is formed. The second pixel contact holes 232 may be respectively arranged in a corresponding manner to the transistors TR located in the odd-numbered columns among the plurality of transistors TR. That is, the second pixel contact hole 232 may be located in an area where the partitioning pattern 223 is not formed. The second pixel contact hole 232 may extend through the planarization layer 220 and the first passivation layer 211. The second pixel contact hole 232 may expose a surface of the source/drain electrode 215 of the transistor TR located in the odd-numbered column.

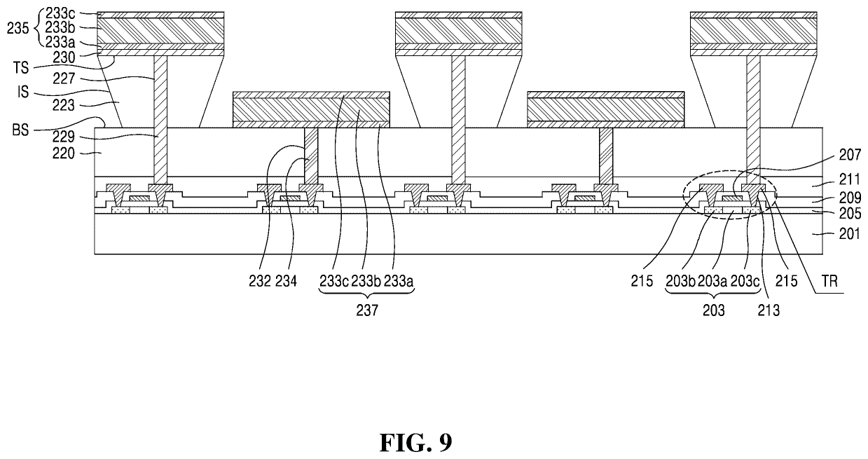

Referring to FIG. 9, the second pixel contact electrode 234 may fill the second pixel contact hole 232. The anode electrodes 235 and 237 that are electrically connected to the source/drain electrodes 215 of each of the plurality of transistors TR may be disposed. The anode electrode 235 and 237 may include the first anode electrode 235 and the second anode electrode 237. The first anode electrode 235 may be disposed on the low-reflective metal pattern 230, and the second anode electrode 237 may be disposed on the planarization layer 220. Accordingly, the upper surfaces of the first anode electrode 235 and the second anode electrode 237 may be positioned at different vertical levels. For example, the upper surface of the second anode electrode 237 may be positioned at a lower vertical level than a vertical level of the upper surface of the first anode electrode 235.

An end of the first anode electrode 235 may be aligned with an end of the partitioning pattern 223. Accordingly, the first anode electrode 235 and the second anode electrode 237 may be positioned to be spaced apart from each other.

In one embodiment, each of the first anode electrode 235 and the second anode electrode 237 may have a multilayer structure. For example, each of the first anode electrode 235 and the second anode electrode 237 may have a structure in which the lower anode electrode 233a, the middle anode electrode 233b, and the upper anode electrode 233c are stacked in this order. The middle anode electrode 233b may be disposed between the lower anode electrode 233a and the upper anode electrode 233c. The middle anode electrode 233b may have the second thickness that is different from the first thickness of each of the lower anode electrode 233a and the upper anode electrode 233c. For example, the first thickness may be smaller than the second thickness. The lower anode electrode 233a and the upper anode electrode 233c may have the same thickness. However, embodiments of the present disclosure are not limited thereto.

The first anode electrode 235 may be electrically connected to the source/drain electrode 215 of the transistor TR located in the even-numbered column.

The second anode electrode 237 may be electrically connected to the source/drain electrode 215 of the transistor TR located in the odd-numbered column. In one example, the lower anode electrode 233a of the second anode electrode 237 may fill the second pixel contact hole 232. Accordingly, a portion of the lower anode electrode 233a may be the second pixel contact electrode 234 that contacts one surface of the source/drain electrode 215 exposed through the second pixel contact hole 232. The second pixel contact electrode 234 may be formed in a different process from a process in which the lower anode electrode 233a is formed. In this case, one surface of the second pixel contact electrode 234 may be electrically connected to the source/drain electrode 215 of the transistor TR, while the other surface thereof may be in contact with the lower surface of the lower anode electrode 233a. The second pixel contact electrode 234 and the lower anode electrode 233a may be made of the same material.

Each of the first and second anode electrodes 235 and 237 may include a transparent metal oxide such as Indium-Tin-Oxide (ITO) or Indium-Zinc-Oxide (IZO). Alternatively, each of the first and second anode electrodes 235 and 237 may have a single-layer or a multi-layer structure including a reflective metal film made of silver (Ag), aluminum (Al), gold (Au), nickel (Ni), chromium (Cr), or a combination thereof. Each of the first and second anode electrodes 235 and 237 may be referred to as a pixel electrode or a first electrode.

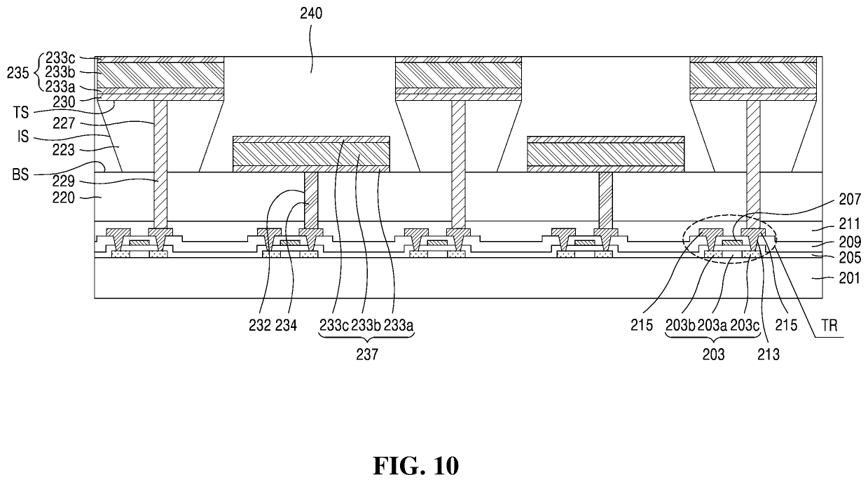

Referring to FIG. 10, a bank material layer 240 is formed on the substrate 201. The bank material layer 240 may cover both the exposed side surface and upper surface of the second anode electrode 237. Furthermore, the bank material layer 240 may be formed to have a thickness sized such that a vertical level of an upper surface thereof is equal to or higher than that of an upper surface of the upper anode electrode 233c of the first anode electrode 235. Accordingly, the side surface IS of the partitioning pattern 223 and the side surface of the first anode electrode 235 may be covered with the bank material layer 240.

The bank material layer 240 may include an organic insulating film such as polyimide or epoxy. In one example, the bank material layer 240 may include one of black resin, graphite, or black ink.

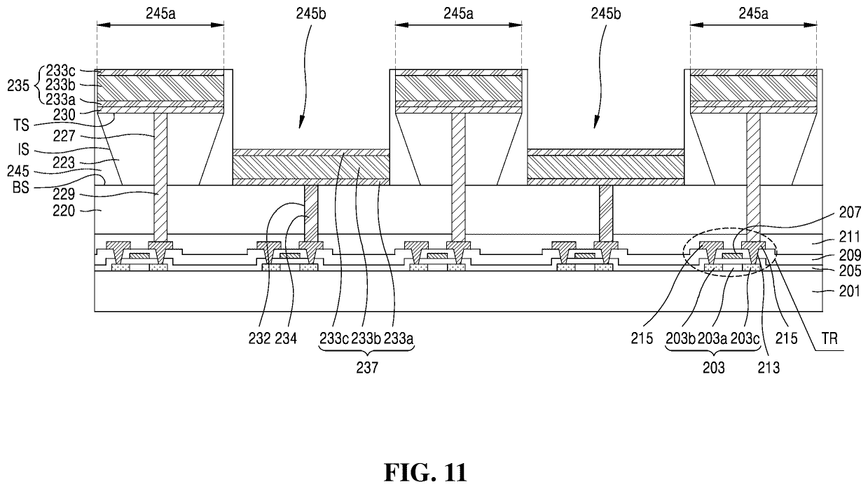

Referring to FIG. 11, exposure and development processes may be performed on the bank material layer 240 to form the bank 245 having the first bank hole 245a and the second bank hole 245b defined therein.

The first and second bank holes 245a and 245b may expose the upper anode electrodes 233c of the first and second anode electrodes 235 and 237, respectively. Each of the first and second bank holes 245a and 245b may be an opening that exposes the light-emission area. That is, an area that is not covered with the bank 245 and is exposed through each of the first and second bank holes 245a and 245b may be defined as the light-emission area where light is emitted.

The side surface of the first anode electrode 235 may be covered with the bank 245. Accordingly, the side surfaces of the lower anode electrode 233a, the middle anode electrode 233b, and the upper anode electrode 233c of the first anode electrode 235 may not be exposed to the outside. Furthermore, the side surface of the second anode electrode 237 may be covered with the bank 245. Accordingly, the side surfaces of the lower anode electrode 233a, the middle anode electrode 233b, and the upper anode electrode 233c of the second anode electrode 237 may not be exposed to the outside.

The bank 245 may include the inner side surface in contact with the side surface of the first anode electrode 235 and the side surface IS of the partitioning pattern 223, and the outer side surface facing the inner side surface. The outer side surface of the bank 245 may be in contact with the side surface of the second anode electrode 237.

In this regard, the second bank hole 245b located between the adjacent first bank holes 245a may be surrounded with the outer side surface of the bank 245. Accordingly, the second bank hole 245b may have a trench shape having an upper surface of the upper anode electrode 233c as a bottom surface thereof and having the outer side surface of the bank 245 as a side wall thereof.

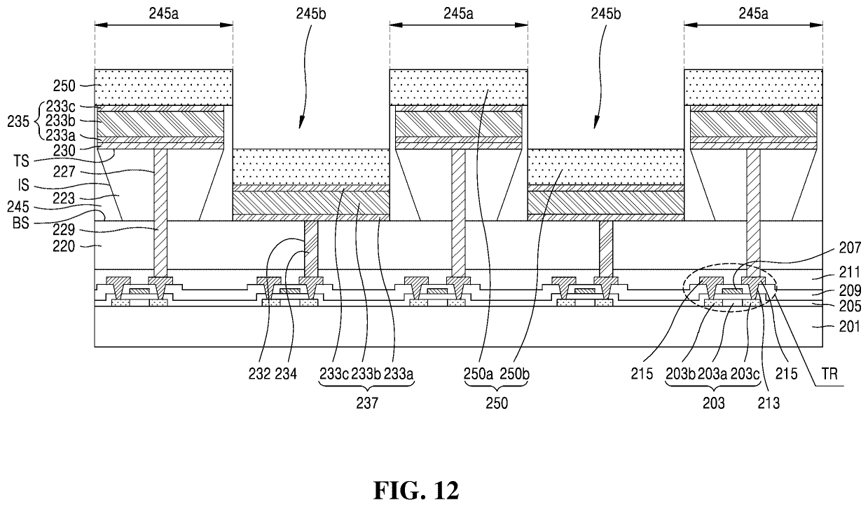

Referring to FIG. 12, the organic light-emitting layer 250 may be disposed on each of the first anode electrode 235 and the second anode electrode 237. The organic light-emitting layer 250 may include the first organic light-emitting layer 250a and the second organic light-emitting layer 250b.

The first organic light-emitting layer 250a may be disposed on the first anode electrode 235, and the second organic light-emitting layer 250b may be disposed on the second anode electrode 237. In one example, each of the first and second organic light-emitting layers 250a and 250b may include an organic material that emits white light.

Each of the first and second organic light-emitting layers 250a and 250b may include a stack structure in which a hole transport layer HTL, a light-emitting layer EML, an electron transport layer ETL, a hole blocking layer HBL, a hole injecting layer HIL, an electron blocking layer EBL, and an electron injecting layer EIL are stacked.

As the upper surfaces of the first anode electrode 235 and the second anode electrode 237 are positioned at different vertical levels, the upper surfaces of the first and second organic light-emitting layers 250a and 250b may be positioned at different vertical levels. For example, the upper surface of the first organic light-emitting layer 250a disposed on the first anode electrode 235 may be positioned at a higher vertical level than a vertical level of the upper surface of the second organic light-emitting layer 250b disposed on the second anode electrode 237.

The bank 245 may include the inner side surface in contact with the side surface of the first anode electrode 235 and the outer side surface facing the inner side surface. An end of the first organic light-emitting layer 250a may be aligned with an end of the bank 245.

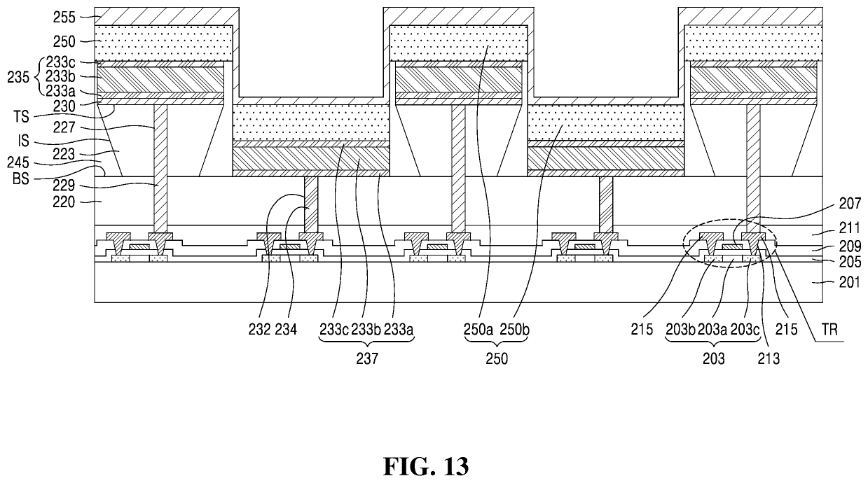

Referring to FIG. 13, the cathode electrode 255 may be formed on the first organic light-emitting layer 250a and the second organic light-emitting layer 250b. The cathode electrode 255 may continuously extend along the entire surface of the substrate 201 in a conformal manner to a profile of a combination of the first organic light-emitting layer 250a and the second organic light-emitting layer 250b. Accordingly, the cathode electrode 255 may have a convex-concave shape.

The cathode electrode 255 may include a semi-transmissive metal material. For example, the cathode electrode 255 may include magnesium (Mg), silver (Ag), or an alloy of magnesium (Mg) and silver (Ag).

The light-emitting element may be configured to include the anode electrodes 235 and 237, the organic light-emitting layer 250, and the cathode electrode 255. When a voltage is applied to the anode electrode 235 and 237 and the cathode electrode 255 based on a selected signal, the light-emitting element emits light through the light-emission area under recombination of the holes injected from the anode electrode 235 or 237 and the electrons injected from the cathode electrode 255.

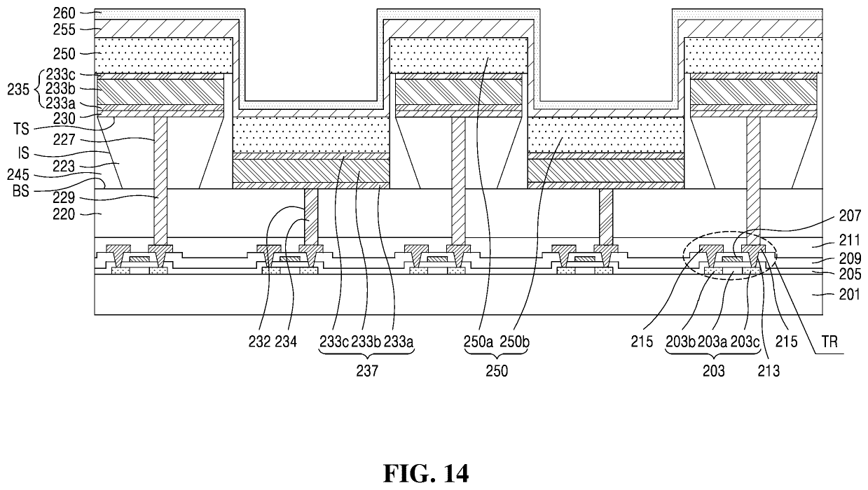

Referring to FIG. 14, the second passivation layer 260 may be formed on the cathode electrode 255. As the second passivation layer 260 is formed along a profile of the cathode electrode 255 in a conformal manner, the second passivation layer 260 may have a concave-convex shape. The second passivation layer 260 may include an insulating material.

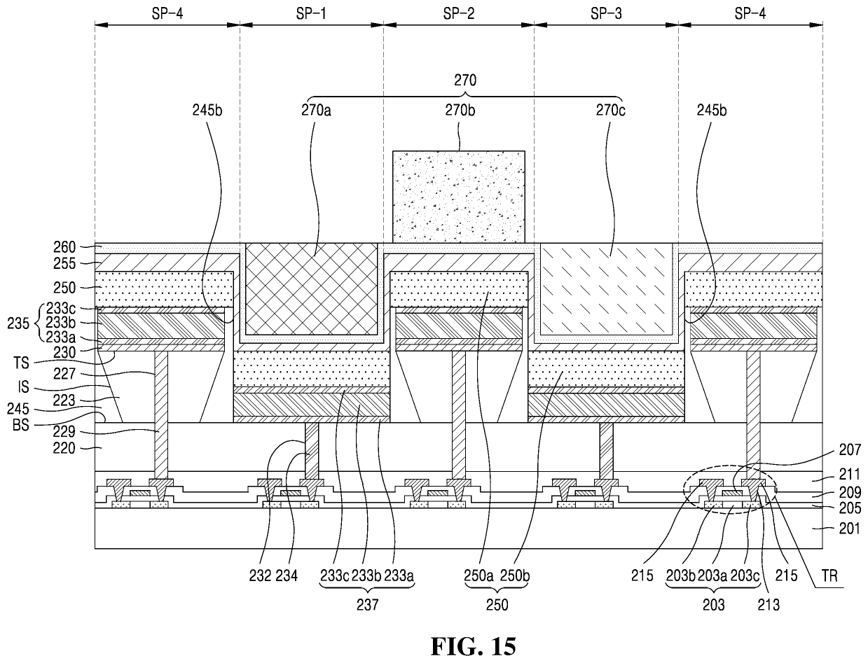

Referring to FIG. 15, the color filter 270 may be disposed on the second passivation layer 260. The color filters 270 may be respectively disposed in a corresponding manner to the sub-pixels SP-1, SP-2, and SP-3 except for the fourth sub-pixel SP-4 which emits white light.

The color filter 270 may include the first color filter 270a, the second color filter 270b, and the third color filter 270c. Each of the first to third color filters 270a, 270b, and 270c may filter white light emitted from the organic light-emitting layer 250 of each of the first to third sub-pixels SP-1, SP-2, and SP-3. As a result, the white light beams having passed through the first to third color filters 270a, 270b, and 270c corresponding to the first to third sub-pixel SP-1, SP-2, and SP-3 may be converted to light beams of different colors which in turn may be emitted to the outside.

The first color filter 270a using a red pigment may be located in a corresponding manner to the first sub-pixel SP-1. The second color filter 270b using a green pigment may be located in a corresponding manner to the second sub-pixel SP-2. The third color filter 270c using a blue pigment may be located in a corresponding manner to the third sub-pixel SP-3.

Accordingly, the first color filter 270a may emit red light, the second color filter 270b may emit green light, and the third color filter 270c may emit blue light. Further, since the color filter corresponding to the fourth sub-pixel SP-4 is not disposed, white light emitted from the organic light-emitting layer 250 may be emitted to the outside in the fourth sub-pixel SP-4.

The first and third color filters 270a and 270c may respectively fill the second bank holes 245b (see FIG. 11) which have the trench shape.

The first to third color filters 270a, 270b, and 270c may be sequentially formed according to colors thereof. For example, the red first color filter 270a may be formed, then, the green second color filter 270b may be formed, and then the blue third color filter 270c may be formed.

In this regard, when the first to third color filters are formed on a flat surface, there is a problem in that it is difficult to control the thicknesses of the color filters to be uniform and a line width of the color filter is reduced. For example, the thickness of the first color filter formed first on the flat surface may be smaller than the thickness of the third color filter formed in a last order on the flat surface. When the color filters have different thicknesses, color mixing between the adjacent sub-pixels may occur and the color may be viewed in a distorted manner in a viewing angle range. Furthermore, as the line width of each color filter decreases, light leakage occurs.

In order to cope with the above problems, in an embodiment of the present disclosure, even when the first color filter 270a, the second color filter 270b, and the third color filter 270c are formed sequentially, the thicknesses of the color filters may be equal to each other. Specifically, in a state in which the first color filter 270a has filled the bank hole 245b having the trench shape in a previous process, the second color filter 270b and the third color filter 270c are sequentially formed in a subsequent process. Thus, the thicknesses of the color filters may be equal to each other. Furthermore, the line width of each color filter may be prevented from being reduced.

Furthermore, the light leakage that the light Ls emitted from the light-emitting element located in the odd-numbered column so as to be directed toward the viewing angle range transmits into the sub-pixels of the light-emitting elements respectively located in the even-numbered columns adjacent to the odd-numbered column may be prevented. For example, the low-reflective metal pattern 230 is disposed under the lower anode electrode 233a of the first anode electrode 235 located in the even-numbered column. The upper surface of the second organic light-emitting layer 250b of the light-emitting element located in the odd-numbered column may be positioned at a lower vertical level than a vertical level of the upper surface of the first organic light-emitting layer 250a of the light-emitting element located in the even-numbered column. In particular, the upper surface of the second organic light-emitting layer 250b of the light-emitting element located in the odd-numbered column is disposed at a lower vertical level than a vertical level of the low-reflective metal pattern 230 under the light-emitting element located in the even-numbered column.

When the voltage is applied to the electrodes such that light is emitted from the light-emitting element located in the odd-numbered column, light Ls emitted from the light-emitting element located in the odd-numbered column so as to be directed toward the viewing angle range may reach and be reflected from the low-reflective metal pattern 230 under the light-emitting element located in each of the even-numbered columns adjacent to the odd-numbered column. Accordingly, the light leakage that the light Ls emitted from the light-emitting element located in the odd-numbered column so as to be directed toward the viewing angle range transmits into the sub-pixels of the light-emitting elements respectively located in the even-numbered columns adjacent to the odd-numbered column may be prevented.

Furthermore, the four sub-pixels including the fourth sub-pixel that emits white light may constitute a unit pixel. Thus, light extraction efficiency may be improved.

FIGS. 16 to 18 are diagrams of head mounted devices including a display apparatus according to an embodiment of the present disclosure.

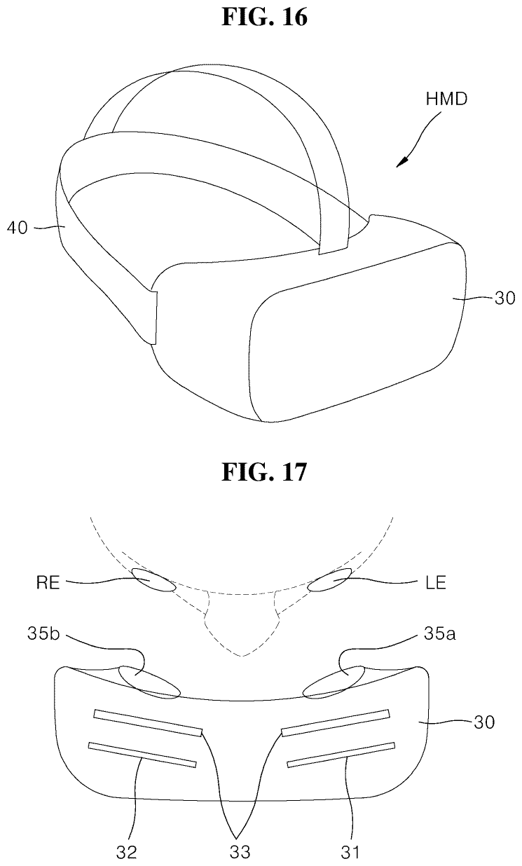

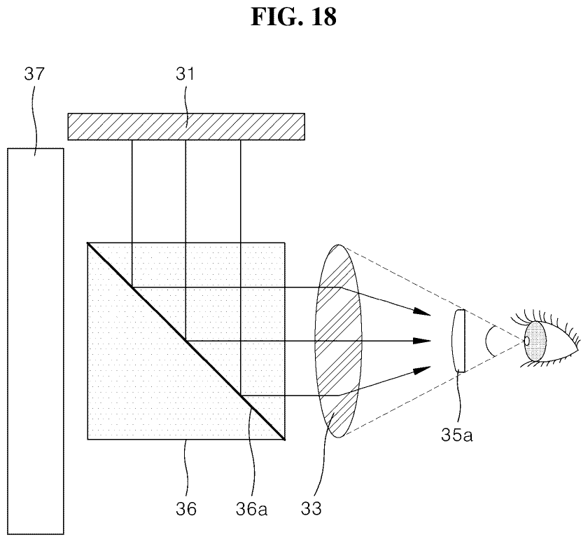

Specifically, FIG. 16 is a schematic perspective view of a head mounted device including a display apparatus according to an embodiment of the present disclosure, and FIG. 17 is a top view showing a head mounted device implementing virtual reality according to an embodiment of the present disclosure. FIG. 18 is a side view showing a head mounted device that implements augmented reality according to an embodiment of the present disclosure.

Referring to FIG. 16, the head mounted device including a display apparatus according to an embodiment of the present disclosure may include a casing 30 and a head mounting band 40.

The casing 30 may receive therein components such as a display apparatus, a lens array, an eyepiece, a sound device, an accelerometer, and a position sensor, etc. The head mounting band 40 is fixed to the casing 30. The head mounting band 40 is illustrated as being formed to surround an upper surface and both opposing side surfaces of the user's head. However, embodiments of the present disclosure are not limited thereto. The head mounting band 40 is used to secure the head mounted device to the user's head. In another example, the head mounting band 40 may be embodied as an eyeglass frame or a helmet-shaped structure that entirely surrounds the user's head.

The head mounted device may include a display apparatus according to an embodiment of the present disclosure as described in FIG. 2 or FIG. 4, and may provide an image implementing virtual reality (VR) or an image implementing augmented reality (AR) to the user.

Referring to FIG. 17, the head-mounted display device that implements virtual reality may include a display apparatus 31 for a left-eye, a display apparatus 32 for right-eye, a lens array 33, and a left-eye eyepiece 35a and a right-eye eyepiece 35b. The display apparatus 31 for a left-eye and the display apparatus 32 for a right-eye, the lens array 33, and the left-eye eyepiece 35a and the right-eye eyepiece 35b may be received in the casing 30.

The display apparatus 31 for a left-eye and the display apparatus 32 for a right-eye may display the same image. When the display apparatus 31 for a left-eye and the display apparatus 32 for a right-eye display the same image, the user may view the 2D image through the head-mounted display device. Alternatively, the display apparatus 31 for a left-eye may display an image for a left-eye, and the display apparatus 32 for a right-eye may display an image for a right-eye that is different from the image for a left-eye. In this case, the user may view a three-dimensional image through the head-mounted display device. Each of the display apparatus 31 for a left-eye and the display apparatus 32 for a right-eye may include the display apparatus according to FIG. 2 or FIG. 4 as described above and one of modifications thereof.

One of the lens array 33 may be spaced apart from each of the left-eye eyepiece 35a and the display apparatus for a left-eye 31, and may be disposed between the left-eye eyepiece 35a and the display apparatus for a left-eye 31. That is, one of the lens array 33 may be located in front of the left-eye eyepiece 35a and in rear of the display apparatus for a left-eye 31. Furthermore, the other of the lens array 33 may be spaced away from each of the right-eye eyepiece 35b and the display apparatus for a right-eye 32, and may be disposed between the right-eye eyepiece 35b and the display apparatus for a right-eye 32. That is, the other of the lens array 33 may be located in front of the right-eye eyepiece 35b and in rear of the display apparatus for a right-eye 32.

The lens array 33 may include, but is not limited to, a micro lens array. In one example, the lens array 33 may include a pin hole array. The image displayed from the display apparatus for a left-eye 31 or the display apparatus for a right-eye 32 may be visible to the user in an enlarged manner due to the lens array 33. The user's left-eye LE may be located in rear of the left-eye eyepiece 35a, and the user's right-eye RE may be located in rear of the right-eye eyepiece 35b.

Referring to FIG. 18, the head-mounted display apparatus that implements augmented reality includes the display apparatus for a left-eye 31, the lens array 33, the left-eye eyepiece 35a, a transmissive and reflective portion 36, and a transmissive window 37. For convenience of illustration, FIG. 18 shows only a configuration related to the left-eye, and a configuration related to the right-eye is the same or similar to the configuration related to the left-eye.

The display apparatus for a left-eye 31, the lens array 33, the left-eye eyepiece 35a, the transmissive and reflective portion 36, and the transmissive window 37 are housed in casing 30 (see FIG. 16). The display apparatus for a left-eye 31 may be disposed on one side of the transmissive and reflective portion 36, for example, on an upper side thereof so that the display apparatus for a left-eye 31 does not block the transmissive window 37. Accordingly, the display apparatus for a left-eye 31 may provide an image to the transmissive and reflective portion 36 without blocking an external background visible through the transmissive window 37.

The display apparatus 31 for a left-eye may include the display apparatus according to FIG. 2 or FIG. 4 or one of modifications thereof. The lens array 33 may be provided between the left-eye eyepiece 35a and the transmissive and reflective portion 36. The user's left-eye may be located in rear of the left-eye eyepiece 35a.

The transmissive and reflective portion 36 is disposed between the lens array 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the display apparatus for a left-eye 31 to be directed to the lens array 33.

Therefore, the user may view both the external background visible through the transmissive window 37 and the image displayed from the display apparatus for a left-eye 31. In other words, the user may view both the real background and the virtual image as one image in an overlapping manner. Thus, the augmented reality may be implemented.

A display apparatus according to various aspects and embodiments of the present disclosure may be described as follows.

One aspect of the present disclosure provides a display apparatus comprising: a substrate having a plurality of sub-pixel areas; a plurality of transistors disposed on the substrate; a planarization layer disposed on the plurality of transistors; a plurality of partitioning patterns disposed on the planarization layer and arranged to be spaced apart from each other; a low-reflective metal pattern disposed on each of the partitioning patterns; an anode electrode disposed on each of the low-reflective metal pattern and the planarization layer and arranged in a corresponding manner to the sub-pixel area; an organic light-emitting layer disposed on the anode electrode; a cathode electrode disposed on the organic light-emitting layer; and a plurality of color filters disposed on the cathode electrode and arranged in a corresponding manner to the plurality of sub-pixel areas, respectively, wherein a vertical level of an upper surface of at least one color filter of the plurality of color filters is higher than a vertical level of an upper surface of the adjacent color filters thereof.

According to some embodiments of the display apparatus, the plurality of color filters have the same thickness.

According to some embodiments of the display apparatus, the display apparatus further comprises: a first pixel contact electrode extending through the partitioning pattern so as to be electrically connected to the transistor; a second pixel contact electrode extending through the planarization layer so as to be electrically connected to the transistor, wherein the first pixel contact electrode is in contact with a lower surface of the low-reflective metal pattern, and the second pixel contact electrode is in contact with a lower surface of the anode electrode disposed on the planarization layer.

According to some embodiments of the display apparatus, the plurality of transistors includes a transistor located in an even-numbered column and a transistor located in an odd-numbered column, wherein each of the plurality of partitioning patterns overlaps the transistor located in the even-numbered column in upper and lower directions.

According to some embodiments of the display apparatus, a width of an upper surface of each of the plurality of partitioning patterns is larger than a width of a lower surface thereof, wherein a side surface of each of the plurality of partitioning patterns extends between the upper surface and the lower surface of each of the plurality of partitioning pattern and in an inclined manner.

According to some embodiments of the display apparatus, the anode electrode includes: a first anode electrode disposed on the low-reflective metal pattern; and a second anode electrode disposed on the planarization layer.

According to some embodiments of the display apparatus, each of the first anode electrode and the second anode electrode includes a lower anode electrode, an upper anode electrode, and a middle anode electrode disposed between the lower anode electrode and the upper anode electrode, wherein the middle anode electrode includes has a thickness different from a thickness of each of the lower anode electrode and the upper anode electrode.

According to some embodiments of the display apparatus, a portion of the lower anode electrode of the second anode electrode extends through the planarization layer so as to be electrically connected to the transistor.

According to some embodiments of the display apparatus, an upper surface of the first anode electrode and an upper surface of the second anode electrode are positioned at different vertical levels, wherein the upper surface of the second anode electrode is positioned at a lower vertical level than a vertical level of the upper surface of the first anode electrode.

According to some embodiments of the display apparatus, the display apparatus further comprises a bank covering both opposing side surfaces of each of the first anode electrode, the second anode electrode, and the partitioning pattern.

According to some embodiments of the display apparatus, the bank includes an inner side surface and an outer side surface facing the inner side surface, wherein the inner side surface of the bank is in contact with the side surface of the first anode electrode and the side surface of the partitioning pattern, wherein the outer side surface of the bank is in contact with the side surface of the second anode electrode.

According to some embodiments of the display apparatus, the bank includes: a first bank hole exposing an upper surface of the first anode electrode; and a second bank hole having a trench shape having an upper surface of the second anode electrode as a bottom surface of the trench, and having the outer side surface of the bank as the side wall of the trench, wherein the second bank hole is disposed between neighboring first bank holes.

According to some embodiments of the display apparatus, the organic light-emitting layer includes an organic material for emitting white light.

According to some embodiments of the display apparatus, the anode electrode includes: a first anode electrode disposed on the low-reflective metal pattern; and a second anode electrode disposed on the planarization layer, wherein the organic light-emitting layer includes: a first organic light-emitting layer disposed on the first anode electrode; and a second organic light-emitting layer disposed on the second anode electrode.

According to some embodiments of the display apparatus, the first organic light-emitting layer and the second organic light-emitting layer are positioned at different vertical levels and are separate from each other.

According to some embodiments of the display apparatus, the display apparatus further comprises a passivation layer disposed between the color filters and the cathode electrode.

According to some embodiments of the display apparatus, the second bank hole is filled with one of the plurality of the color filters.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A display apparatus comprising:
a substrate having a plurality of sub-pixel areas;
a plurality of transistors on the substrate;
a planarization layer on the plurality of transistors;
a plurality of partitioning patterns on the planarization layer and spaced apart from each other;
a plurality of low-reflective metal patterns respectively on the partitioning patterns;
a plurality of anode electrodes respectively on the low-reflective metal patterns and the planarization layer, and arranged in a corresponding manner to the plurality of sub-pixel area, respectively;
an organic light-emitting layer on the anode electrodes;
a cathode electrode on the organic light-emitting layer; and
a plurality of color filters on the cathode electrode and corresponding to some sub-pixel areas of the plurality of sub-pixel areas, respectively,
wherein a vertical level of an upper surface of at least one color filter among the plurality of color filters is higher than a vertical level of an upper surface of another color filter adjacent to the at least one color filter.

2. The display apparatus of claim 1, wherein the plurality of color filters have a same thickness.

3. The display apparatus of claim 1, wherein the plurality of transistors includes a transistor located in an even-numbered column and a transistor located in an odd-numbered column,
wherein each of the plurality of partitioning patterns overlaps the transistor located in the even-numbered column in upper and lower directions.

4. The display apparatus of claim 3, wherein the display apparatus further comprises:
a plurality of first pixel contact electrodes respectively through at least one partitioning pattern of the plurality of partitioning patterns so as to be electrically connected to at least one transistor of the plurality of transistors located in an odd-numbered column; and
a plurality of second pixel contact electrodes respectively extending through the planarization layer so as to be electrically connected to the at least one transistor of the plurality of transistors located in an even-numbered column,
wherein each of the first pixel contact electrodes is in contact with a lower surface of each of the low-reflective metal patterns, and each of the second pixel contact electrodes is in contact with a lower surface of each of the anode electrodes disposed on the planarization layer.

5. The display apparatus of claim 1, wherein a width of an upper surface of each of the plurality of partitioning patterns is larger than a width of a lower surface thereof,
wherein a side surface of each of the plurality of partitioning patterns extends between the upper surface and the lower surface of each of the plurality of partitioning patterns in an inclined manner.

6. The display apparatus of claim 1, wherein plurality of anode electrodes include:
a first anode electrode on the low-reflective metal pattern; and
a second anode electrode on the planarization layer.

7. The display apparatus of claim 6, wherein each of the first anode electrode and the second anode electrode includes a lower anode electrode, an upper anode electrode, and a middle anode electrode between the lower anode electrode and the upper anode electrode,
wherein the middle anode electrode has a thickness different from a thickness of each of the lower anode electrode and the upper anode electrode.

8. The display apparatus of claim 7, wherein a portion of the lower anode electrode of the second anode electrode extends through the planarization layer so as to be electrically connected to at least one transistor of the plurality of transistors.

9. The display apparatus of claim 6, wherein an upper surface of the first anode electrode and an upper surface of the second anode electrode are positioned at different vertical levels,
wherein the upper surface of the second anode electrode is positioned at a lower vertical level than a vertical level of the upper surface of the first anode electrode.

10. The display apparatus of claim 6, wherein the display apparatus further comprises a bank covering both opposing side surfaces of each of the first anode electrode, the second anode electrode, and at least one partitioning pattern of the plurality of partitioning patterns.

11. The display apparatus of claim 10, wherein the bank includes an inner side surface and an outer side surface facing the inner side surface,
wherein the inner side surface of the bank is in contact with a side surface of the first anode electrode and the side surface of the at least one partitioning pattern of the plurality of partitioning patterns,
wherein the outer side surface of the bank is in contact with a side surface of the second anode electrode.

12. The display apparatus of claim 11, wherein the bank includes:
a first bank hole exposing an upper surface of the first anode electrode; and
a second bank hole having a trench shape having an upper surface of the second anode electrode as a bottom surface of the trench shape, and having the outer side surface of the bank as a side wall of the trench shape,
wherein the second bank hole is between neighboring first bank holes.

13. The display apparatus of claim 1, wherein the organic light-emitting layer includes an organic material for emitting white light.

14. The display apparatus of claim 1, wherein the plurality of anode electrodes include:
a first anode electrode on the low-reflective metal pattern; and
a second anode electrode on the planarization layer,
wherein the organic light-emitting layer includes:
a first organic light-emitting layer on the first anode electrode; and
a second organic light-emitting layer on the second anode electrode.

15. The display apparatus of claim 14, wherein the first organic light-emitting layer and the second organic light-emitting layer are positioned at different vertical levels and are separate from each other.

16. The display apparatus of claim 1, wherein the display apparatus further comprises a passivation layer between the plurality of color filters and the cathode electrode.

17. The display apparatus of claim 12, wherein the second bank hole is filled with at least one color filter of the plurality of color filters.

18. The display apparatus of claim 17, wherein the plurality of the color filters include a first color filter, a second color filter and a third color filter, and the first color filter and the third color filter fill respective second bank holes, respectively.

19. The display apparatus of claim 18, wherein the first color filter, the second color filter and the third color filter have same line width.

20. The display apparatus of claim 15, wherein the cathode electrode is formed in a concave-convex shape in a conformal manner to a profile of a combination of the first organic light-emitting layer and the second organic light-emitting.

21. The display apparatus of claim 20, wherein the partitioning patterns include a same organic insulating material as that of the planarization layer.

22. A method for manufacturing a display apparatus comprises:
providing a substrate having a plurality of sub-pixel areas;
disposing a plurality of transistors on the substrate;
disposing a planarization layer over the plurality of transistors;
disposing a plurality of partitioning patterns on the planarization layer to make the plurality of partitioning patterns be spaced apart from each other;
disposing low-reflective metal patterns on each of the partitioning patterns;
disposing anode electrodes on each of the low-reflective metal patterns and the planarization layer and arranging the anode electrodes in a corresponding manner to the plurality of sub-pixel areas, respectively;
disposing an organic light-emitting layer on the anode electrodes;
disposing a cathode electrode on the organic light-emitting layer; and
disposing a plurality of color filters on the cathode electrode and arranging the plurality of color filters in a corresponding manner to some of the plurality of sub-pixel areas, respectively,
wherein a vertical level of an upper surface of at least one color filter among the plurality of color filters is higher than a vertical level of an upper surface of another color filter adjacent to the at least one color filter.
